(19) United States
(12) Patent Application Publication
(10) Pub. No.: US 2026/0181922 A1
(43) Pub. Date: Jun. 25, 2026

(54) SEMICONDUCTOR STRUCTURE AND MANUFACTURING METHOD THEREOF

(71) Applicant: Winbond Electronics Corp., Taichung City (TW)

(72) Inventor: Ming-Chih Hsu, Taichung City (TW)

(73) Assignee: Winbond Electronics Corp., Taichung City (TW)

(21) Appl. No.: 19/051,170

(22) Filed: Feb. 12, 2025

(30) Foreign Application Priority Data
Dec. 25, 2024 (TW) 113150571

(51) Int. Cl. H10D 1/68; H10D 1/00

(52) U.S. Cl. CPC H10D 1/716; H10D 1/043; H10D 1/696

(57) ABSTRACT

A capacitor structure including a substrate, a first support layer, and a capacitor is provided. The first support layer is located on the substrate. The capacitor is located on the substrate. The capacitor includes a bottom electrode, a top electrode, and a dielectric layer. The bottom electrode includes a first portion and a second portion. The first portion is located on capacitor holes passing through the first support layer. The second portion is electrically connected to the first portion and covers a bottom surface of the first support layer. The top electrode is located on the bottom electrode. The dielectric layer is located between the bottom electrode and the top electrode.

### CROSS-REFERENCE TO RELATED APPLICATION

This application claims the priority benefit of Taiwan application serial no. 113150571, filed on Dec. 25, 2024. The entirety of the above-mentioned patent application is hereby incorporated by reference herein and made a part of this specification.

### BACKGROUND

### Technical Field

The disclosure relates to a semiconductor structure and a manufacturing method thereof, and in particular relates to a capacitor structure having a cylindrical capacitor and a manufacturing method thereof.

### Description of Related Art

Cylindrical capacitors are semiconductor elements widely used in electronic products. However, as the size of cylindrical capacitors shrinks, the ongoing objective remains to further enhance the capacitance and yield of the cylindrical capacitors. For example, in conventional cylindrical capacitors, the bottom electrodes of multiple cylindrical capacitors are separated, which is prone to generating defects of bottom electrode stripping, thereby reducing yield. Furthermore, there is a bottleneck in terms of increasing capacitance.

### SUMMARY

A capacitor structure and a manufacturing method thereof, which may improve the defects of the above-mentioned bottom electrode and break through the bottleneck in terms of increasing capacitance, are provided in the disclosure.

A capacitor structure, which includes a substrate, a first support layer and a capacitor, is proposed in the disclosure. The first support layer is located on the substrate. The capacitor is located on the substrate. The capacitor includes a bottom electrode, a top electrode, and a dielectric layer. The bottom electrode includes a first portion and a second portion. The first portion is located on multiple capacitor holes passing through the first support layer. The second portion is electrically connected to the first portion and covers a bottom surface of the first support layer. The top electrode is located on the bottom electrode. The dielectric layer is located between the bottom electrode and the top electrode.

A manufacturing method of a capacitor structure is provided in the disclosure, in which the manufacturing method includes the following operation. A first support layer is formed on the substrate. A bottom electrode of the capacitor is formed. The bottom electrode includes a first portion and a second portion. The first portion is formed on multiple capacitor holes passing through the first support layer. The second portion is electrically connected to the first portion and covers a bottom surface of the first support layer. A dielectric layer of the capacitor is formed on the bottom electrode. A top electrode of the capacitor is formed on the dielectric layer.

Based on the above, in the capacitor structure proposed by the disclosure, the bottom electrode includes a first portion and a second portion. The second portion covers the bottom surface of the first support layer and is even formed in the cavity. In this way, the second portion of the bottom electrode may provide additional coupling area, thereby effectively increasing the capacitance of the capacitor structure and potentially offering a greater yield margin. In addition, the second portion of the bottom electrode may effectively increase the structural strength of the capacitor structure, thereby improving the quality of the capacitor structure.

### BRIEF DESCRIPTION OF THE DRAWINGS

FIG. 1A to FIG. 1M are top views of a manufacturing process of a capacitor structure according to some embodiments of the disclosure.

FIG. 2A to FIG. 2M are cross-sectional diagrams along the section line I-I′ in FIG. 1A to FIG. 1M.

FIG. 3A to FIG. 3B are top views of a manufacturing process of a capacitor structure according to other embodiments of the disclosure.

FIG. 4A to FIG. 4B are cross-sectional diagrams along the section line I-I′ in FIG. 3A to FIG. 3B.

FIG. 5 is a cross-sectional diagram of a capacitor structure according to other embodiments of the disclosure.

FIG. 6 is a top view of the electrode layer 118a and the support layer 114 in FIG. 5.

FIG. 7 is a cross-sectional diagram of a capacitor structure according to other embodiments of the disclosure.

FIG. 8 is a top view of the electrode layer 118a and the support layer 114 in FIG. 7.

### DETAILED DESCRIPTION OF DISCLOSED EMBODIMENTS

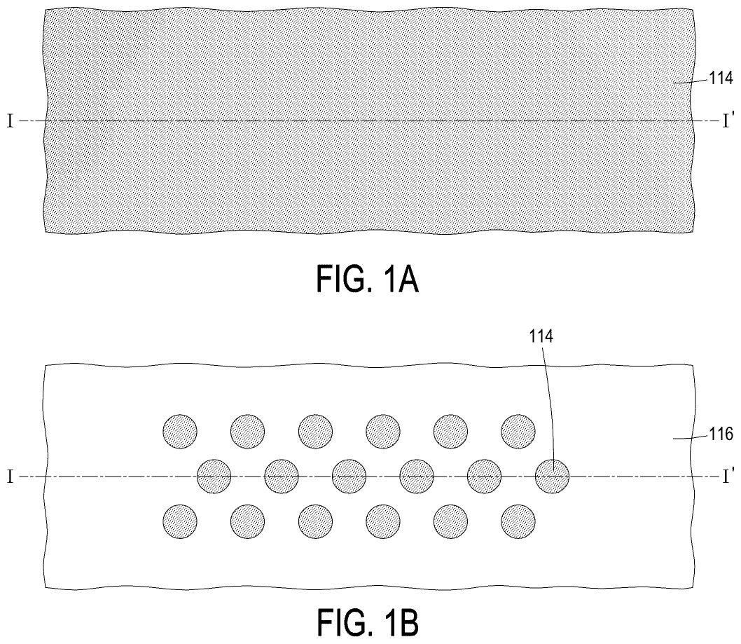

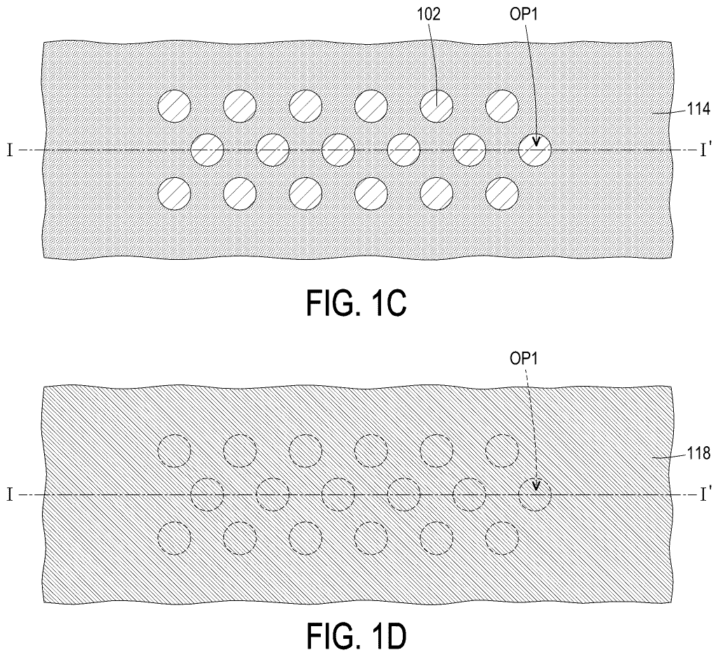

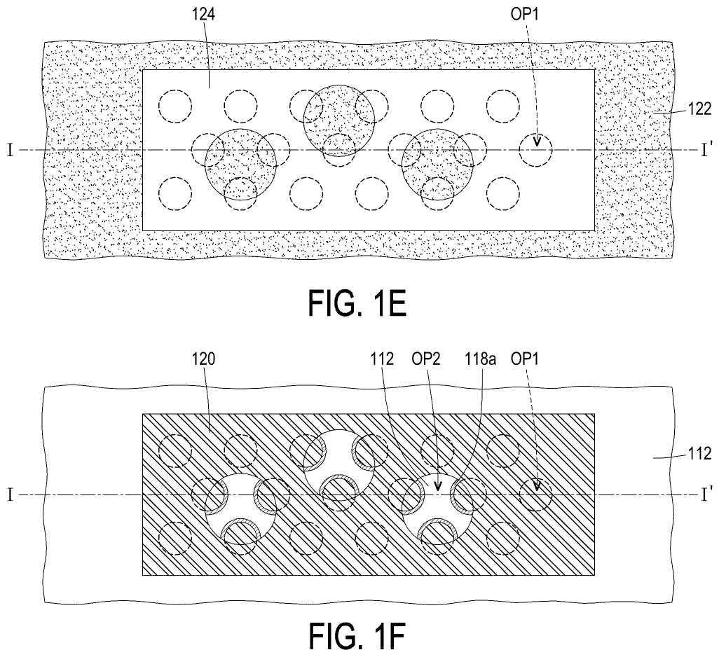

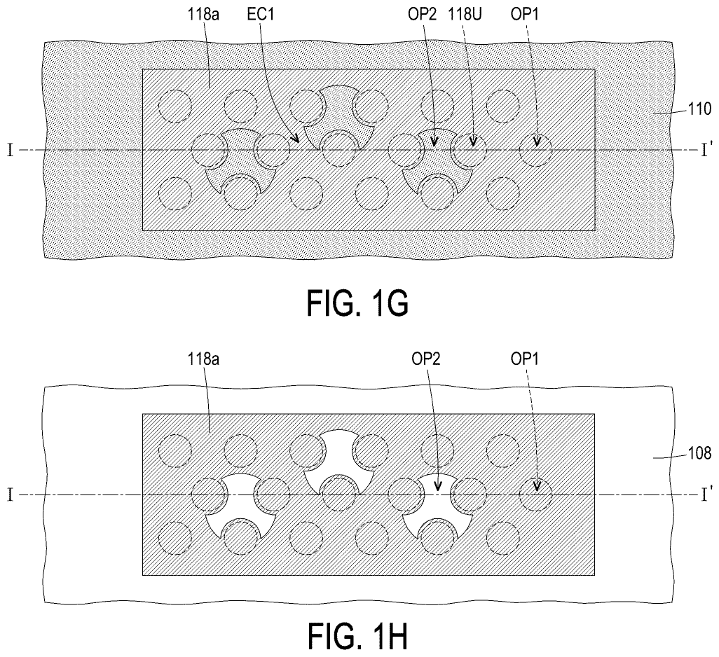

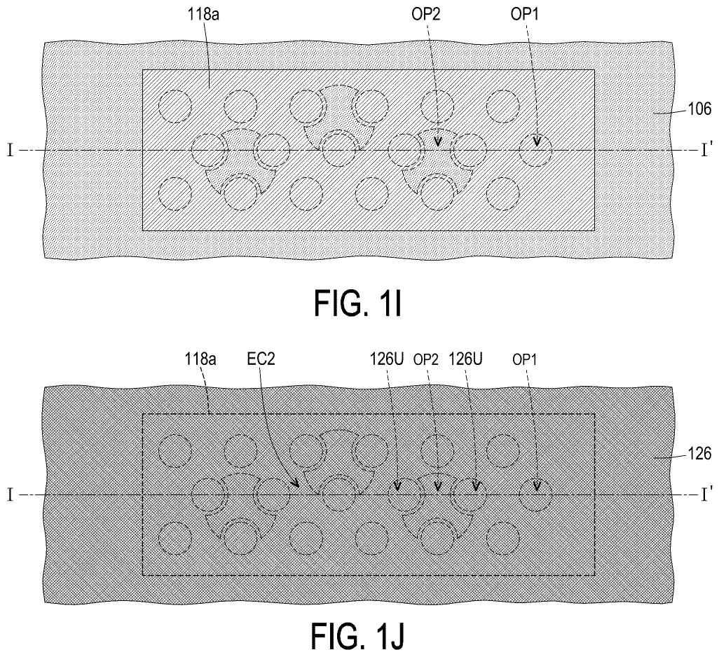

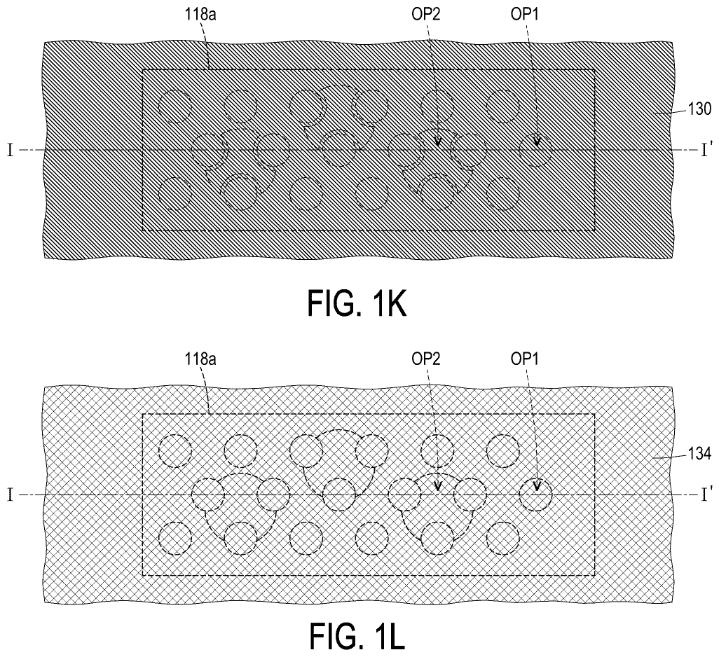

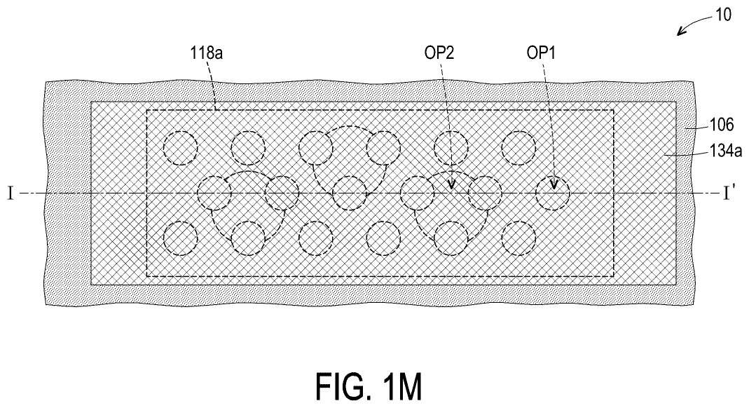

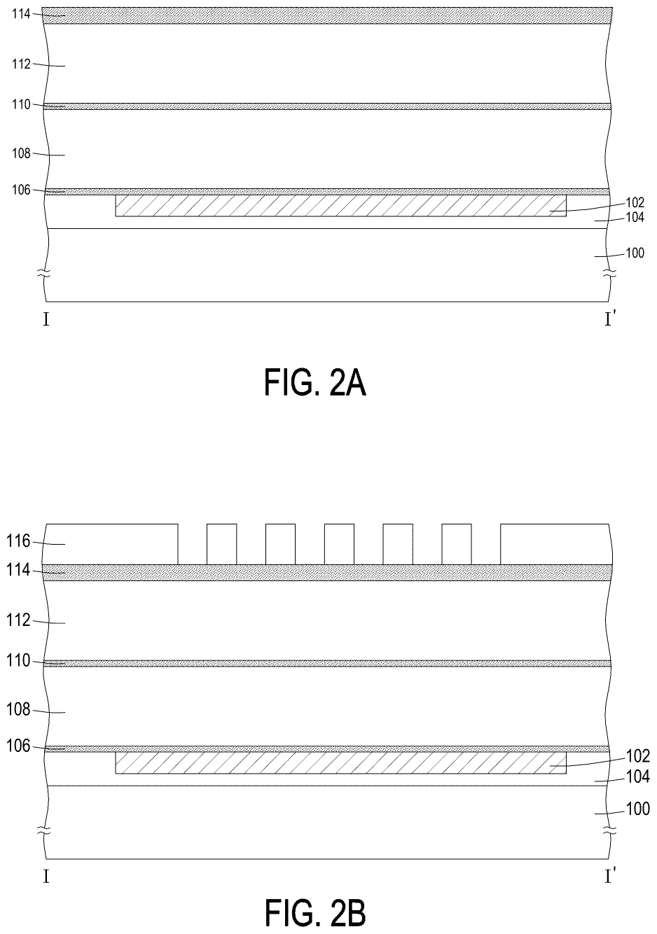

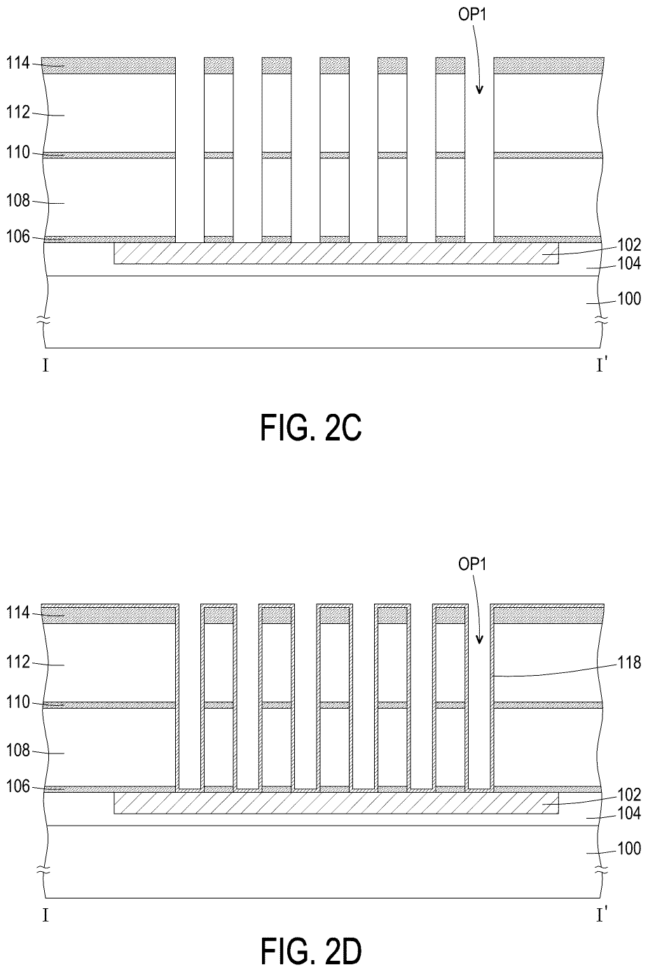

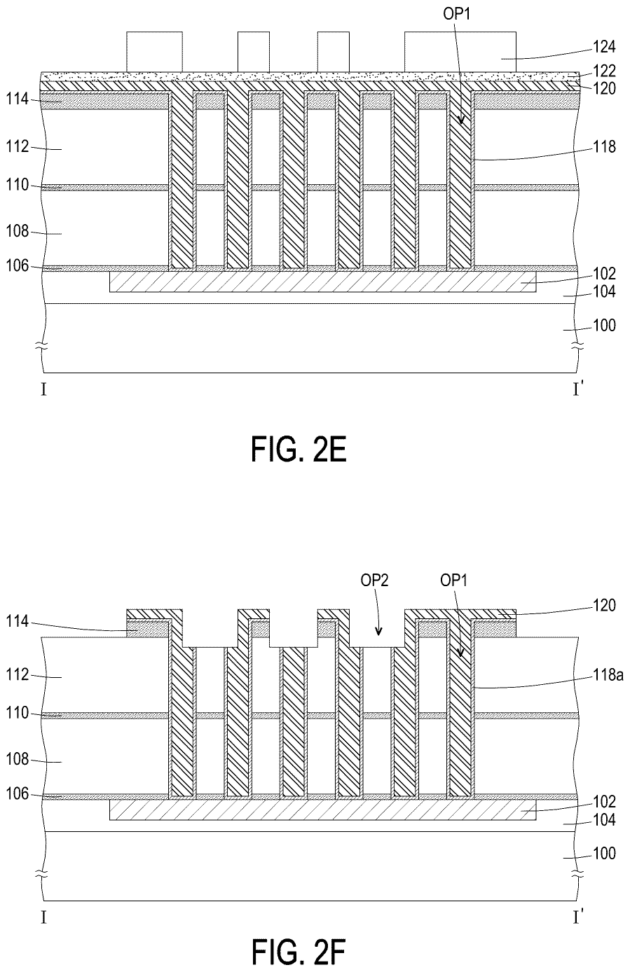

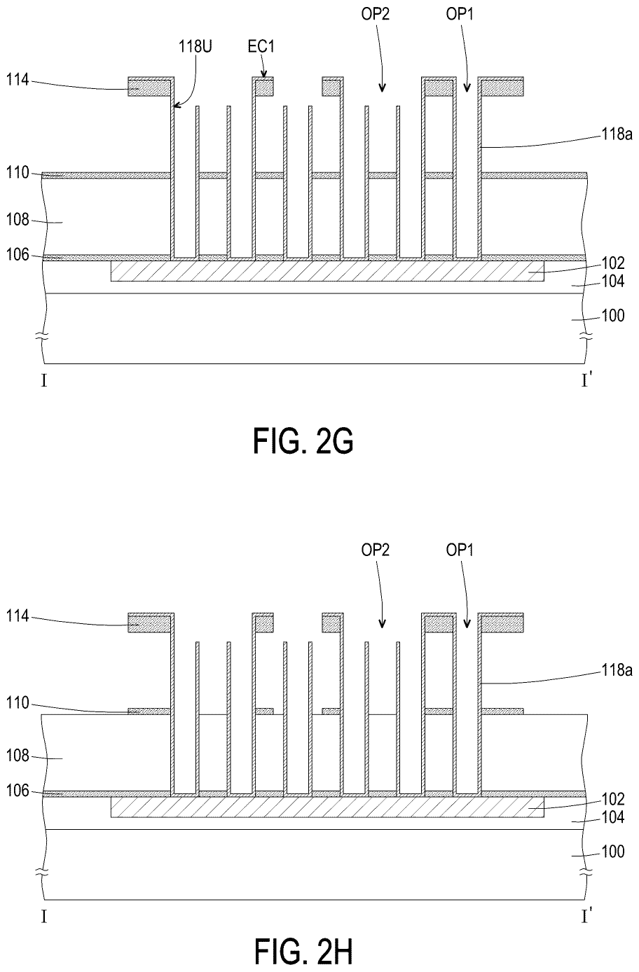

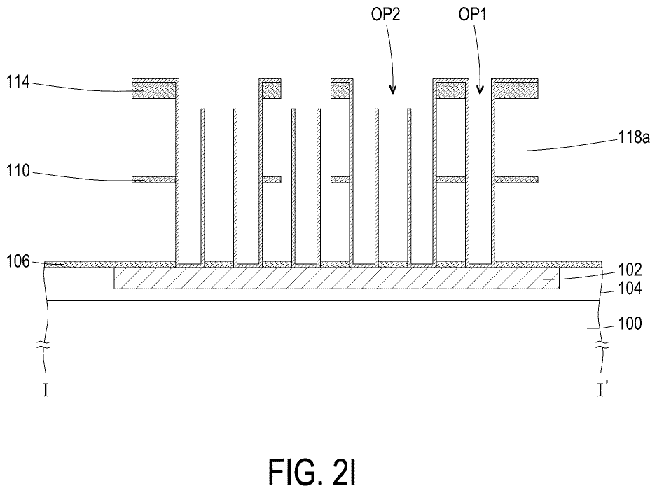

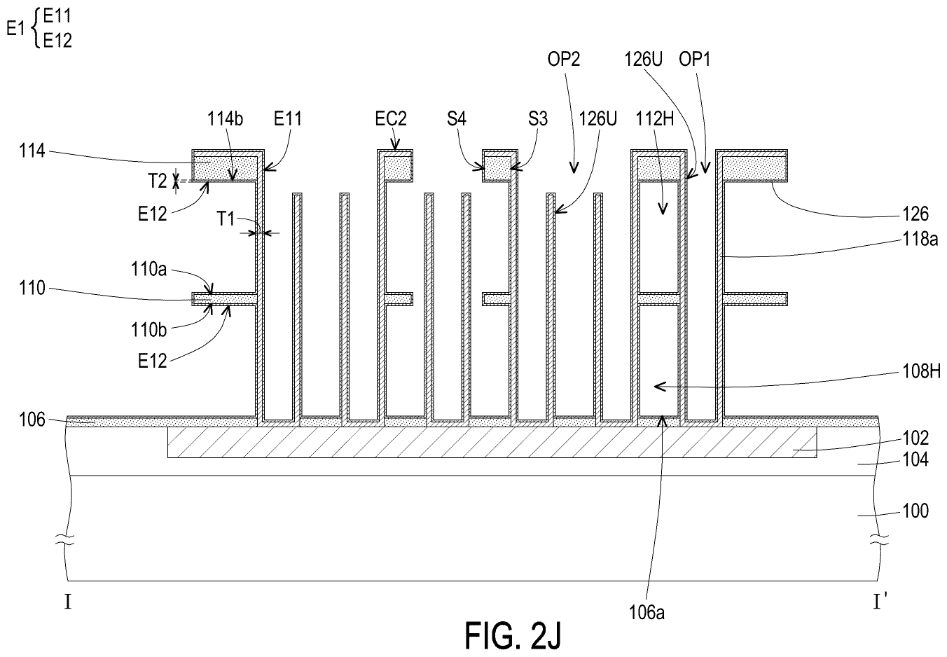

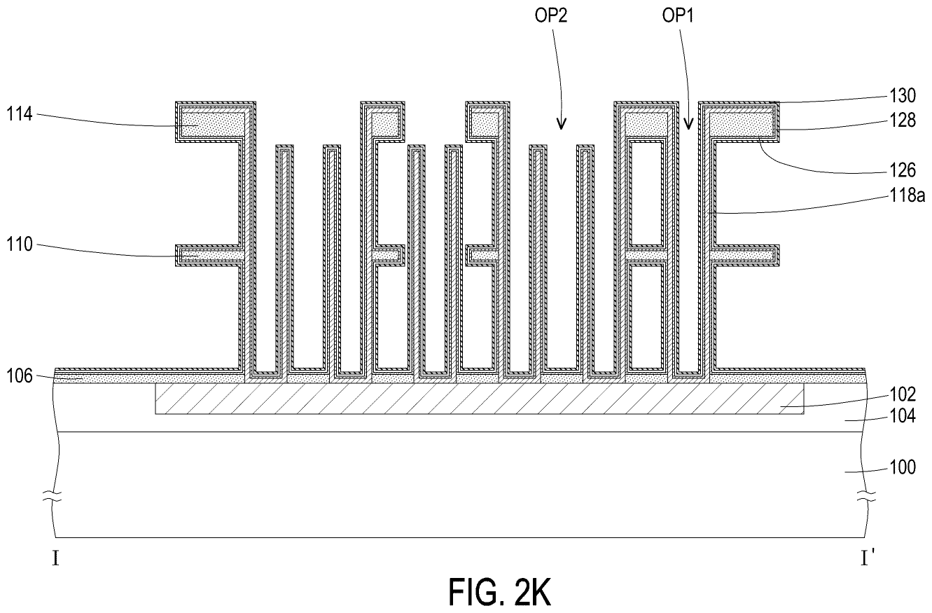

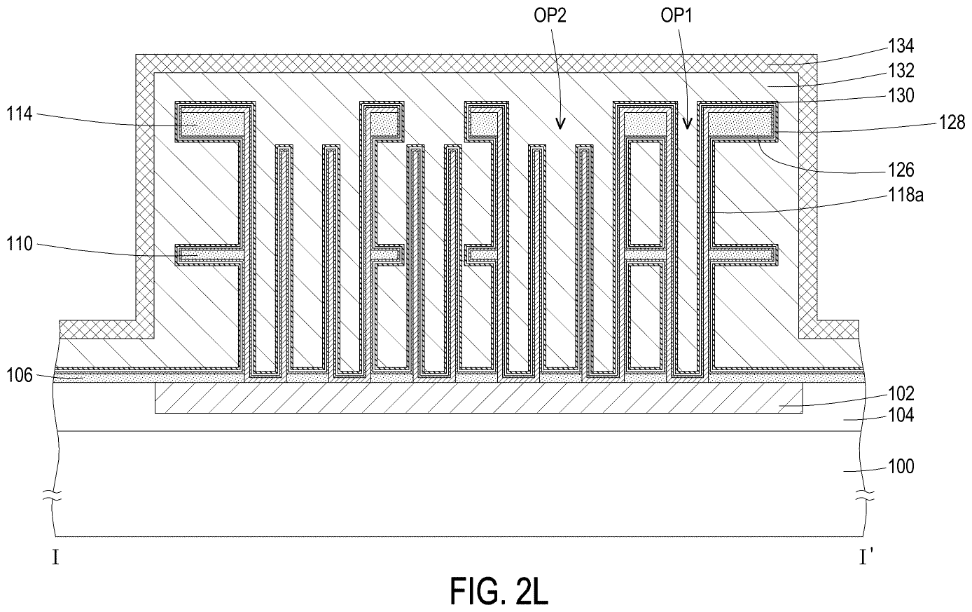

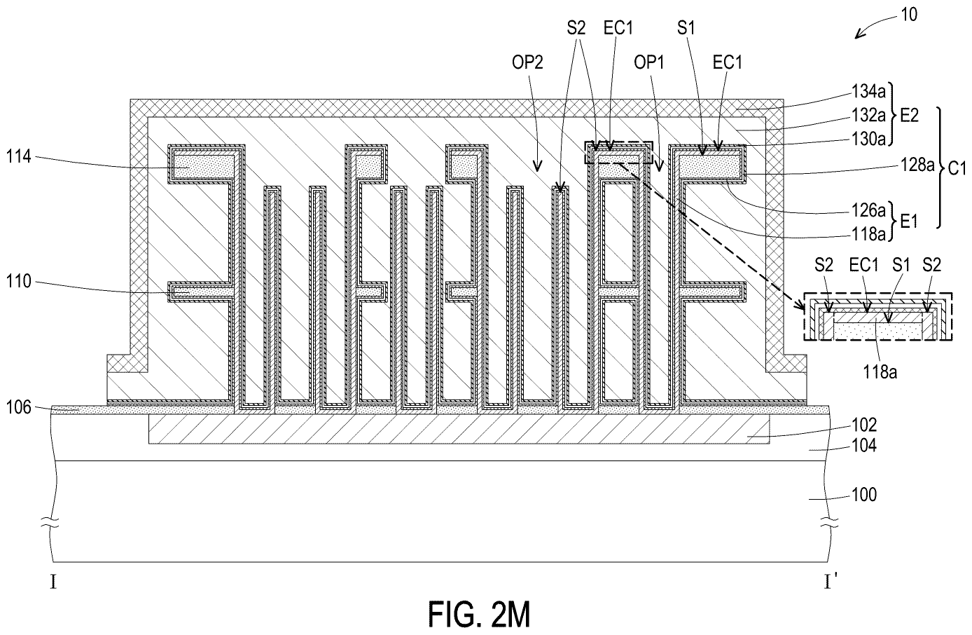

Embodiments are enumerated below for detailed description. In order to facilitate understanding, the same components in the following description are described with the same symbols. FIG. 1A to FIG. 1M are top views of a manufacturing process of a capacitor structure according to some embodiments of the disclosure. FIG. 2A to FIG. 2M are cross-sectional diagrams along the section line I-I′ in FIG. 1A to FIG. 1M.

Referring to FIG. 1A and FIG. 2A, a dielectric layer 104 may be formed on the substrate 100, and a conductive plate 102 may be formed in the dielectric layer 104. Then, a termination layer 106, a sacrificial layer 108, a support layer 110, a sacrificial layer 112, and a support layer 114 may be sequentially formed on the conductive plate 102 and the dielectric layer 104. The substrate 100 may be a semiconductor substrate, such as a silicon substrate. In other embodiments, the substrate 100 may be silicon on insulator (SOI). The material of the conductive plate 102 may metal, such as tungsten or copper. In another embodiment, the conductive plate 102 may be a doped region (not shown) formed in the active region of the substrate 100. The material of the termination layer 106 may be a suitable etch stop dielectric material. The material of the support layer 110 and the support layer 114 may be a suitable support dielectric material. In this embodiment, the material of the termination layer 106, the support layer 110, and the support layer 114 is, for example, a nitride (e.g., silicon nitride). In addition, the material of the sacrificial layer 108 and the sacrificial layer 112 may be a dielectric material having an etching selectivity ratio with the support layers 110 and 114, such as an oxide (e.g., silicon oxide).

Referring to FIG. 1B and FIG. 2B, a patterned photoresist layer 116 may be formed on the support layer 114. Referring to FIG. 1C and FIG. 2C, the support layer 114, the sacrificial layer 112, the support layer 110, the sacrificial layer 108, and the termination layer 106 may be patterned by using the patterned photoresist layer 116 as a mask, thereby forming multiple capacitor holes OP1 in the support layer 114, the sacrificial layer 112, the support layer 110, the sacrificial layer 108, and the termination layer 106. In other words, the capacitor hole OP1 may pass through the support layer 114, the support layer 110 and the termination layer 106, and expose the conductive plate 102. Then, the patterned photoresist layer 116 may be removed.

Referring to FIG. 1D and FIG. 2D, an electrode material layer 118 may be formed conformally on the support layer 114 and in the capacitor hole OP1.

Referring to FIG. 1E and FIG. 2E, a filling layer 120 may be formed on the electrode material layer 118 and in the capacitor hole OP1. The material of the filling layer 120 is, for example, an oxide (e.g., silicon oxide). Next, a hard mask layer 122 may be formed on the filling layer 120. The hard mask layer 122 may be a single-layer structure or a multi-layer structure. The material of the hard mask layer 122 is, for example, carbon, silicon oxynitride, or a combination thereof. Then, a patterned photoresist layer 124 may be formed on the hard mask layer 122.

Referring to FIG. 1F and FIG. 2F, firstly, the hard mask layer 122 may be patterned by using the patterned photoresist layer 124 as a mask to form the patterned hard mask layer 122. Next, the patterned photoresist layer 124 may be removed. Then, the filling layer 120, the electrode material layer 118, and the support layer 114 may be patterned by using the patterned hard mask layer 122 as a mask, and the patterned electrode material layer 118 forms the electrode layer 118a. Thereby, multiple openings OP2 that pass through the support layer 114 and expose a portion of the sacrificial layer 112, the electrode layer 118a and the filling layer 120 may be formed. Each opening OP2 is connected to multiple capacitor holes OP1 on which the electrode layer 118a has been formed. The patterned hard mask layer 122 may be consumed during the above process or removed later.

Referring to FIG. 1G and FIG. 2G, the filling layer 120 and the sacrificial layer 112 may be removed by, for example, a wet etching method. Referring to FIG. 1H and FIG. 2H, a portion of the support layer 110 may be removed by, for example, a dry etching method to expose a portion of the sacrificial layer 108. Next, referring to FIG. 1I and FIG. 2I, the sacrificial layer 108 may be removed by, for example, a wet etching method to deepen the opening OP2 to be located between the electrode layers 118a and expose the termination layer 106. As shown in FIG. 2I, the electrode layer 118a may connect the support layer 114, the support layer 110 and the termination layer 106, and is supported by the support layer 114 and the support layer 110 to prevent collapse.

Referring to FIG. 1J and FIG. 2J, an electrode material layer 126 covering the electrode layer 118a, the support layer 114, the support layer 110, and the termination layer 106 may be formed.

Referring to FIG. 1K and FIG. 2K, a dielectric material layer 128 and an electrode material layer 130 may be sequentially formed on the electrode material layer 126. The material of the dielectric material layer 128 is, for example, a high dielectric constant material.

Referring to FIG. 1L and FIG. 2L, an electrode material layer 132 and an electrode material layer 134 may be sequentially formed on the electrode material layer 130. The material of the electrode material layer 132 is, for example, doped silicon germanium, such as boron doped silicon germanium (B-doped SiGe). The material of the electrode material layer 134 is, for example, conductive material such as tungsten.

In this embodiment, the termination layer 106, the sacrificial layer 108, the support layer 110, the sacrificial layer 112, the support layer 114, the electrode material layers 118, 126, 130 and 134, and the dielectric material layer 128 may be respectively formed by chemical vapor deposition, but the disclosure is not limited thereto. The material of the electrode material layers 118, 126, and 130 is, for example, a conductive material such as titanium nitride (TiN), but the disclosure is not limited thereto.

Referring to FIG. 1M and FIG. 2M, the electrode material layer 134, the electrode material layer 132, the electrode material layer 130, the dielectric material layer 128 and the electrode material layer 126 may be patterned to form the electrode layer 134a, the electrode layer 132a, the electrode layer 130a, the dielectric layer 128a and the electrode layer 126a, and the termination layer 106 in the peripheral region is exposed.

Hereinafter, the capacitor structure 10 of this embodiment will be described with reference to FIG. 1M and FIG. 2M. In addition, although the forming method of the capacitor structure 10 is described by taking the above-mentioned method as an example, the disclosure is not limited thereto. For clarity, elements related to the bottom electrode E1 are labeled in FIG. 2J.

Referring to FIG. 1M, FIG. 2J, and FIG. 2M, the capacitor structure 10 includes a substrate 100, a support layer 114 and a capacitor C1. The support layer 114 is located on substrate 100. The capacitor C1 is located on substrate 100. The capacitor C1 includes a bottom electrode E1, a top electrode E2, and a dielectric layer 128a. The bottom electrode E1 includes a first portion E11 and a second portion E12. The first portion E11 of the bottom electrode E1 is located on multiple capacitor holes OP1 passing through the support layer 114. The first portion E11 of the bottom electrode E1 connects these capacitor holes OP1. In addition, in this embodiment, the first portion E11 of the bottom electrode E1 may also cover the top surface S1 and the first side wall S3 of the support layer 114. In this embodiment, the first portion E11 of the bottom electrode E1 includes an electrode layer 118a and an electrode layer 126a, and has a first thickness T1. The second portion E12 of the bottom electrode E1 is electrically connected to the first portion E11 of the bottom electrode E1 and covers the bottom surface 114b of the support layer 114. In this embodiment, the second portion E12 of the bottom electrode E1 includes the electrode layer 126a and may have a second thickness T2 that is less than the first thickness T1 (labeled in FIG. 2J). In addition, in this embodiment, the second portion E12 of the bottom electrode E1 further covers the second side wall S4 of the support layer 114, and the first side wall S3 is opposite to the second side wall S4. The second portion E12 of the bottom electrode E1 connects these capacitor holes OP1. A portion of the second portion E12 of the bottom electrode E1 may be located in the cavity 112H defined by the first portion E11 of the bottom electrode E1 and the support layer 114. Thereby, additional coupling area provided by the second portion E12 of the bottom electrode E1 optimizes electrical performance, and the capacitance and structural strength of the capacitor structure 10 may be improved.

In addition, in this embodiment, as shown in FIG. 1G and FIG. 2G, the electrode layer 118a may include multiple U-shaped cross-sectional structures 118U formed in the capacitor holes OP1 and a planar structure EC1 connecting these U-shaped cross-sectional structures 118U, but the disclosure is not limited thereto. The planar structure EC1 of the electrode layer 118a may be located on the top surface S1 of the support layer 114. Through the above-mentioned step of forming the opening OP2, the electrode layer 118a may have multiple top surfaces S2 (labeled in FIG. 2M) located at different heights, thereby facilitating the removal of the sacrificial layers 108 and 112 and the formation of the electrode material layer 126 and the dielectric material layer 128. As shown in FIG. 1J, FIG. 2J, and FIG. 2M, the electrode layer 126a includes multiple U-shaped cross-sectional structures 126U formed in the capacitor holes OP1 and openings OP2, and a planar structure EC2 connecting these U-shaped cross-sectional structures. The electrode layer 126a covers the support layer 114 and the electrode layer 118a, and the electrode layer 126a is electrically connected to the electrode layer 118a. Thereby, the capacitance and structural strength of the capacitor structure 10 may be effectively improved. Referring to FIG. 2M, the top electrode E2 is located on the bottom electrode E1, and the dielectric layer 128a is located between the bottom electrode E1 and the top electrode E2. In this embodiment, the top electrode E2 located on the dielectric layer 128a may sequentially include the electrode layers 130a, 132a, and 134a.

The capacitor structure 10 may further include a conductive plate 102 and a dielectric layer 104. The conductive plate 102 is located below the first portion E11 of the bottom electrode E1 and is electrically connected to the bottom electrode E1. In this embodiment, the conductive plate 102 may be directly connected to the electrode layer 118a.

The capacitor structure 10 may further include a support layer 110 between the support layer 114 and the substrate 100. The capacitor hole OP1 and the opening OP2 pass through the support layer 110. The second portion E12 of the bottom electrode E1 may cover the top surface 110a and the bottom surface 110b of the support layer 110. In this embodiment, a portion of the second portion E12 of the bottom electrode E1 may be located in the cavity 108H defined by the first portion E11, the support layer 110, and the termination layer 106. Besides, a portion of the second portion E12 of the bottom electrode E1 may be located in the cavity 112H defined by the first portion E11 of the bottom electrode E1 and the support layer 114, and the support layer 110. Thereby, the capacitance and structural strength of the capacitor structure 10 may be improved.

The capacitor structure 10 may further include a termination layer 106. The capacitor hole OP1 passes through the termination layer 106, and the opening OP2 does not pass through the termination layer 106. The second portion E12 of the bottom electrode E1 further covers the top surface 106a of the termination layer 106. The termination layer 106 is located between the conductive plate 102 and the second portion E12 of the bottom electrode E1. The electrode layer 118a may be connected to the termination layer 106. The electrode layer 126a may cover a portion of the termination layer 106.

In addition, the details of each component in the capacitor structure 10 (e.g., materials and forming methods, etc.) have been described in detail in the above embodiments and are not repeated herein.

Based on the above embodiment, the bottom electrode E1 of the capacitor structure 10 includes a first portion E11 and a second portion E12. The second portion E12 covers the bottom surface 114b of the support layer 114 and is even formed in the cavities 112H and 108H. Compared with the conventional capacitor structure in which the bottom electrode does not cover the bottom surface of the support layer and is not formed in the cavity, the capacitor structure 10 of this embodiment may provide additional coupling area, thereby effectively increasing the capacitance of the capacitor structure 10 and potentially offering a greater yield margin. In addition, the capacitor structure 10 of this embodiment effectively improves the structural strength of the bottom electrode E1 by means of the planar structure EC2 connecting these U-shaped cross-sectional structures 126U and/or the planar structure EC1 connecting these U-shaped cross-sectional structures 118U, thereby improving the quality of the capacitor structure 10.

The following describes other variations according to the disclosure, in which the same or similar components are represented by the same symbols. The same description is omitted, and only the differences may be stated.

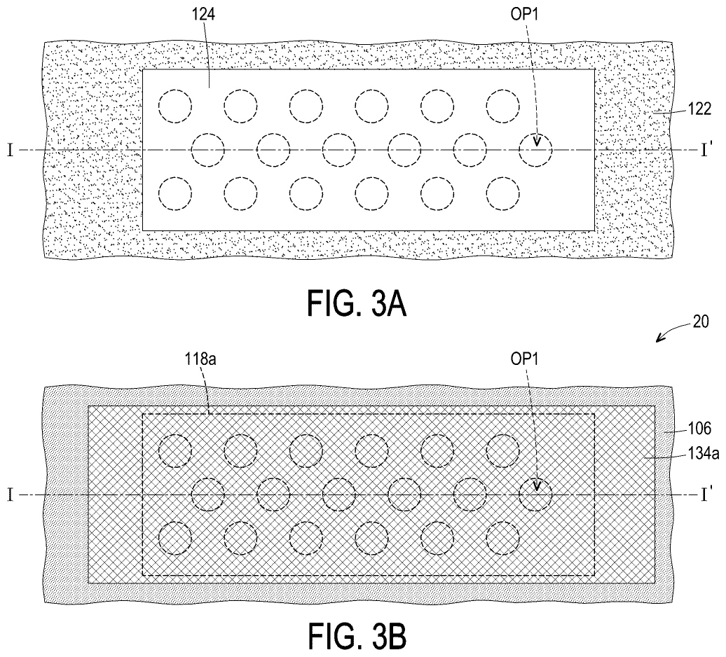

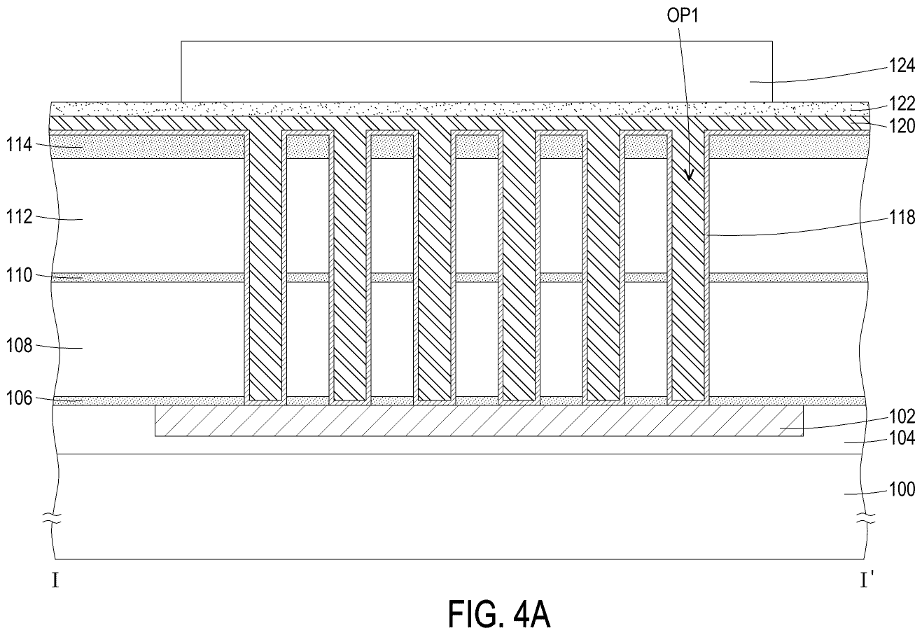

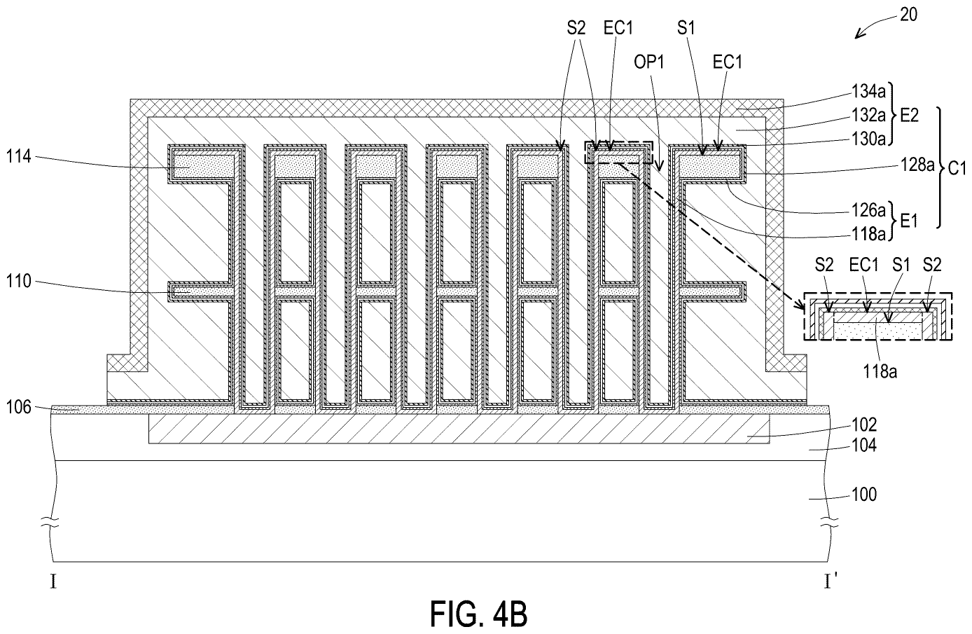

FIG. 3A to FIG. 3B are top views of a manufacturing process of a capacitor structure according to other embodiments of the disclosure. FIG. 4A to FIG. 4B are cross-sectional diagrams along the section line I-I′ in FIG. 3A to FIG. 3B.

Referring to FIG. 3A and FIG. 4A, steps similar to those shown in FIG. 1E and FIG. 2E may be performed to obtain the structure of FIG. 3A and FIG. 4A. The difference lies in that the pattern of the patterned photoresist layer 124 in FIG. 3A and FIG. 4A differs from the pattern of the patterned photoresist layer 124 in FIG. 1E and FIG. 2E.

Next, steps similar to those shown in FIG. 1F to FIG. 1M and FIG. 2F to FIG. 2M may be performed to obtain the capacitor structure 20 in FIG. 3B and FIG. 4B. The differences between the capacitor structure 20 and the capacitor structure 10 are as follow. In capacitor structure 20, all top surfaces S2 of the electrode layer 118a may have the same height. In other words, the capacitor structure 20 does not have the step of forming the opening OP2.

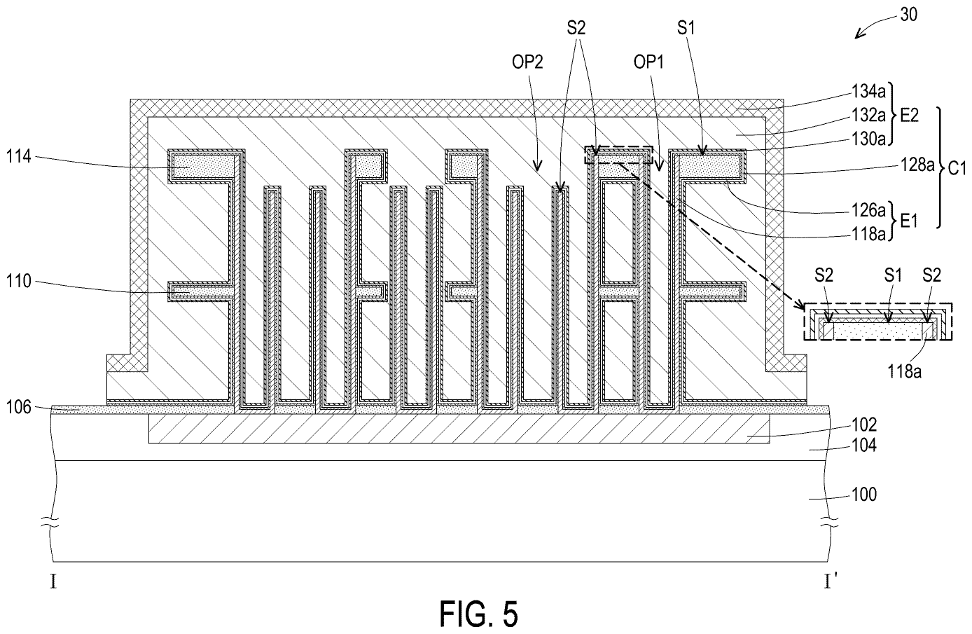

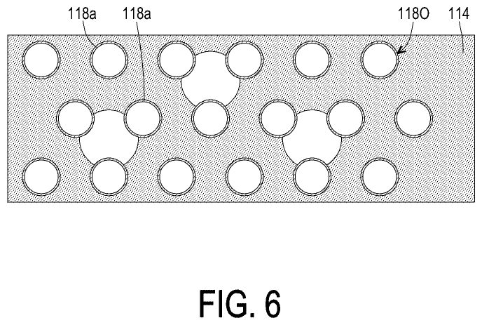

FIG. 5 is a cross-sectional diagram of a capacitor structure according to other embodiments of the disclosure. FIG. 6 is a top view of the electrode layer 118a and the support layer 114 in FIG. 5.

Referring to FIG. 2M and FIG. 5, the differences in the manufacturing method and the structure between the capacitor structure 30 and the capacitor structure 10 are as follows. In the manufacturing method of the capacitor structure 30, after the electrode layer 118a is formed, a portion of the electrode layer 118a located on the top surface S1 of the support layer 114 may be removed. Thereby, in the capacitor structure 30, the electrode layer 118a is not located on the top surface S1 of the support layer 114, and the electrode layer 118a does not include the planar structure EC1 as shown in FIG. 2M. In this way, in the capacitor structure 30, the first portion (including the electrode layers 118a and 126a) of the bottom electrode E1 covers a first side wall of the support layer 114, the second portion (including the electrode layer 126a) of the bottom electrode E1 further covers a second side wall and a top surface S1 of the support layer 114, and the first side wall is opposite to the second side wall. As shown in FIG. 6, in the capacitor structure 30, the electrode layer 118a may form multiple separated circular structures 118O having a U-shaped cross section.

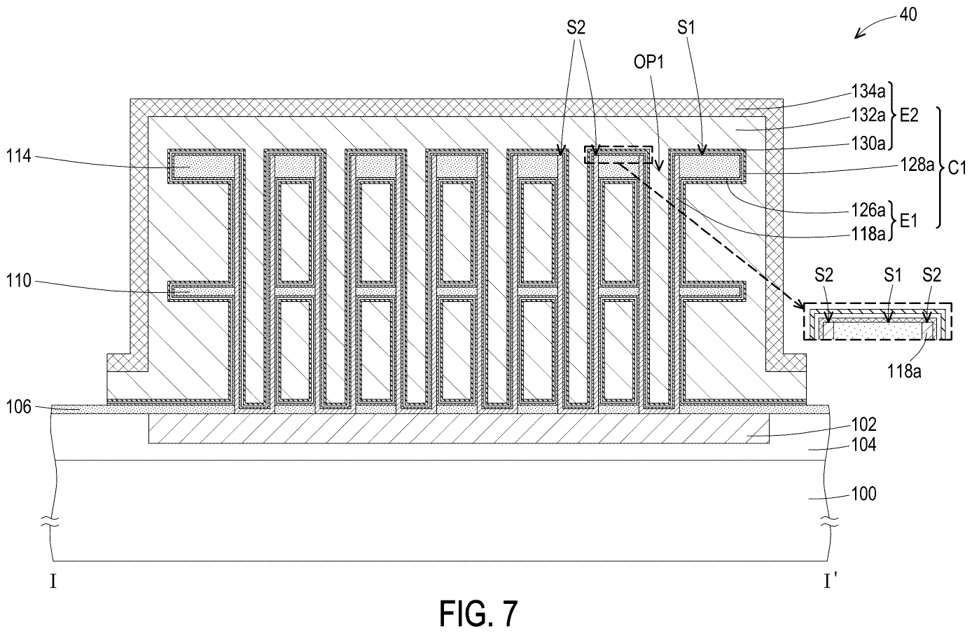

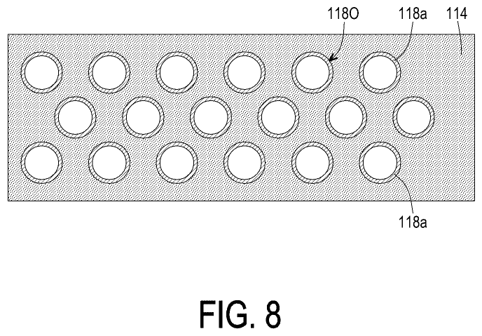

FIG. 7 is a cross-sectional diagram of a capacitor structure according to other embodiments of the disclosure. FIG. 8 is a top view of the electrode layer 118a and the support layer 114 in FIG. 7.

Referring to FIG. 4B and FIG. 7, the differences in the manufacturing method and the structure between the capacitor structure 40 and the capacitor structure 20 are as follows. In the manufacturing method of the capacitor structure 40, after the electrode layer 118a is formed, a portion of the electrode layer 118a located on the top surface S1 of the support layer 114 may be removed. Thereby, in the capacitor structure 40, the electrode layer 118a is not located on the top surface S1 of the support layer 114, and the electrode layer 118a does not include the planar structure EC1 as shown in FIG. 4B. As shown in FIG. 8, in the capacitor structure 40, the electrode layer 118a may form multiple separated circular structures 118O having a U-shaped cross section.

According to the embodiments of the disclosure, it contributes to improving the structural strength and capacitance of the capacitor structure, and facilitates in improving the yield rate. In addition, the disclosure is suitable for fabricating miniaturized capacitor structures to increase the total number of die on the wafer. Therefore, the disclosure may reduce the production cost and energy consumption of manufacturing a single IC, and reduce the production energy consumption of subsequent packaging, thereby reducing carbon emissions in the production process of semiconductor structures. Therefore, the disclosure provides an environmentally friendly semiconductor technology.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A semiconductor structure, comprising:
a substrate;
a first support layer, located on the substrate; and
a capacitor, located on the substrate, and comprising:
a bottom electrode, comprising:
a first portion, located on a plurality of capacitor holes passing through the first support layer; and
a second portion, electrically connected to the first portion and covering a bottom surface of the first support layer;
a top electrode, located on the bottom electrode; and
a dielectric layer, located between the bottom electrode and the top electrode.

2. The semiconductor structure according to claim 1, wherein the first portion of the bottom electrode has a first thickness, and the second portion has a second thickness that is less than the first thickness.

3. The semiconductor structure according to claim 1, wherein a portion of the second portion of the bottom electrode is located in a cavity defined by the first portion and the first support layer.

4. The semiconductor structure according to claim 1, wherein the first portion of the bottom electrode covers a top surface and a first side wall of the first support layer, the second portion of the bottom electrode further covers a second side wall of the first support layer, and the first side wall is opposite to the second side wall.

5. The semiconductor structure according to claim 1, wherein the first portion of the bottom electrode covers a top surface, a first side wall, and a second side wall of the first support layer, and the first side wall is opposite to the second side wall.

6. The semiconductor structure according to claim 1, further comprising:
a second support layer, located between the first support layer and the substrate, wherein the capacitor holes pass through the second support layer, and the second portion of the bottom electrode covers a top surface and a bottom surface of the second support layer.

7. The semiconductor structure according to claim 6, wherein the second portion of the bottom electrode is located in a cavity defined by the first portion, the first support layer, and the second support layer.

8. The semiconductor structure according to claim 1, wherein the first portion of the bottom electrode connects the capacitor holes.

9. The semiconductor structure according to claim 1, wherein the second portion of the bottom electrode connects the capacitor holes.

10. The semiconductor structure according to claim 1, further comprising:
a conductive plate, electrically connected to the bottom electrode and located below the first portion of the bottom electrode; and
a termination layer, wherein the capacitor holes pass through the termination layer, the second portion of the bottom electrode further covers a top surface of the termination layer, and the termination layer is located between the conductive plate and the second portion of the bottom electrode.

11. The semiconductor structure according to claim 10, wherein a portion of the second portion of the bottom electrode is located in a cavity defined by the first portion, the second support layer, and the termination layer.

12. The semiconductor structure according to claim 2, wherein the first portion of the bottom electrode covers a first side wall of the first support layer, the second portion of the bottom electrode further covers a second side wall and a top surface of the first support layer, and the first side wall is opposite to the second side wall.

13. A manufacturing method of a semiconductor structure, comprising:
forming a first support layer on a substrate;
forming a bottom electrode of a capacitor, the bottom electrode comprising:
a first portion, formed on a plurality of capacitor holes passing through the first support layer; and
a second portion, electrically connected to the first portion and covering a bottom surface of the first support layer;
forming a dielectric layer of the capacitor on the bottom electrode; and
forming a top electrode of the capacitor on the dielectric layer.

14. The manufacturing method of the semiconductor structure according to claim 13, wherein forming the bottom electrode of the capacitor comprises:
forming a first electrode layer in the capacitor holes;
forming a second electrode layer on the first electrode layer and the first support layer, wherein the first portion of the bottom electrode has a first thickness, and the second portion has a second thickness that is less than the first thickness.

15. The manufacturing method of the semiconductor structure according to claim 13, further comprising:
forming a second support layer between the first support layer and the substrate, wherein the capacitor holes pass through the second support layer, and the second portion of the bottom electrode covers a top surface and a bottom surface of the second support layer.

16. The manufacturing method of the semiconductor structure according to claim 15, wherein a portion of the second portion of the bottom electrode is located in a cavity defined by the first portion, the first support layer, and the second support layer.

17. The manufacturing method of the semiconductor structure according to claim 13, wherein the first portion of the bottom electrode connects the capacitor holes.

18. The manufacturing method of the semiconductor structure according to claim 13, wherein the second portion of the bottom electrode connects the capacitor holes.

19. The manufacturing method of the semiconductor structure according to claim 13, further comprising:
forming a conductive plate before forming the first support layer, wherein the conductive plate is electrically connected to the bottom electrode and is located below the first portion of the bottom electrode; and
forming a termination layer on the conductive plate, wherein the capacitor holes pass through the termination layer, and the second portion of the bottom electrode further covers a top surface of the termination layer.

20. The manufacturing method of the semiconductor structure according to claim 19, wherein a portion of the second portion of the bottom electrode is located in a cavity defined by the first portion, the second support layer, and the termination layer.
